(19) United States
(12) Patent Application Publication
(10) Pub. No.: US 2025/0253203 A1
(43) Pub. Date: Aug. 7, 2025

(54) METAL CERAMIC SUBSTRATE AND METHOD FOR PRODUCING THE SAME

(71) Applicant: TONG HSING ELECTRONIC INDUSTRIES, LTD., Taipei City (TW)

(72) Inventors: CHIH-WEI MAO, Taipei City (TW); TSUNG-YING CHANG, Taipei City (TW); CHUNG-HO WEI, Taipei City (TW); MING-YI HSU, Taipei City (TW); CHI-WEN HUANG, Taipei City (TW)

(21) Appl. No.: 18/651,755

(22) Filed: May 1, 2024

(30) Foreign Application Priority Data
Feb. 6, 2024 (TW) 113104612

(51) Int. Cl. H01L 23/373; H01L 21/48

(52) U.S. Cl. CPC H01L 23/3735; H01L 21/4807

(57) ABSTRACT

A metal ceramic substrate and a method for producing the same are provided. The metal ceramic substrate includes a ceramic substrate layer, a metal solder layer, and a conductive metal layer. The metal solder layer includes a first sub-solder layer and a second sub-solder layer. The first sub-solder layer is disposed on a side surface of the ceramic substrate layer. A composition of the first sub-solder layer includes a first metal solder material, and the first metal solder material includes a metal copper and an active metal, and does not include a metal silver. The second sub-solder layer is disposed on a side surface of the first sub-solder layer. A composition of the second sub-solder layer includes a second metal solder material. The second metal solder material includes a metal tin and a metal copper, and does not include a metal silver.

### CROSS-REFERENCE TO RELATED PATENT APPLICATION

This application claims the benefit of priority to Taiwan Patent Application No. 113104612, filed on Feb. 6, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a substrate, and more particularly to a metal ceramic substrate and a method for producing the same.

### BACKGROUND OF THE DISCLOSURE

With the promotion of energy-saving and carbon reduction policies in various countries, the global market for electric vehicles (EV) is currently booming. In recent years, as major automakers successively launch 800-volt high-voltage vehicle products, demands for silicon carbide (SiC) ceramic substrate materials have grown rapidly.

However, for power devices that are based on the silicon carbide (SiC) ceramic substrate materials, requirements on a voltage, a frequency, and an operating temperature thereof are constantly increased. Hence, the ceramic substrate materials also need to be improved in terms of heat dissipation and reliability.

In the related art, conventional direct-bonding-copper (DBC) ceramic substrates are prepared by eutectic bonding, and there is no bonding material between a copper layer and a ceramic substrate. However, in the process of a high-temperature operation, a large thermal stress is often generated due to differences in thermal expansion coefficients between the copper layer and the ceramic substrate (e.g., Al₂O₃ or AlN), which causes the copper layer to peel off from a surface of the ceramic substrate. Therefore, the conventional direct-bonding-copper (DBC) ceramic substrates can no longer meet packaging requirements of high temperature, high power, high heat dissipation, and high reliability.

Currently, the conventional direct-bonding-copper (DBC) ceramic substrates are gradually being replaced in popularity by active metal brazing (AMB) substrate materials. Active metals (e.g., Ti, Zr, Ta, Nb, V, or Hf) of the active metal brazing substrate materials can wet a side surface of a ceramic substrate, so as to braze an ultra-thick copper foil onto the ceramic substrate at a high temperature. A brazing layer formed between the ultra-thick copper foil and the ceramic substrate through the active metal brazing process has a high connection strength.

In conventional active metal brazing paste materials, a silver-copper-titanium (Ag—Cu—Ti) metal composite material is commonly used. In the above-mentioned silver-copper-titanium metal composite material, a silver content usually exceeds 50 weight percent (weight percent concentration), and can even exceed 70 weight percent.

A brazing temperature of the conventional active metal brazing paste material that adopts the silver-copper-titanium (Ag—Cu—Ti) metal composite material is usually greater than 900° C. (e.g., 915° C.). Since a brazing layer formed of the conventional active metal brazing paste material contains a large amount of silver (i.e., a noble metal), material and manufacturing costs of the active metal brazing ceramic substrates remain high. Furthermore, the problem of electro-migration caused by silver (Ag) residue after an etching process has long been an issue that needs be solved.

### SUMMARY OF THE DISCLOSURE

In response to the above-referenced technical inadequacies, the present disclosure provides a metal ceramic substrate and a method for producing the same.

In order to solve the above-mentioned problems, one of the technical aspects adopted by the present disclosure is to provide a metal ceramic substrate. The metal ceramic substrate includes a ceramic substrate layer, a metal solder layer, and a conductive metal layer. The metal solder layer includes a first sub-solder layer and a second sub-solder layer. The first sub-solder layer is disposed on a side surface of the ceramic substrate layer. A composition of the first sub-solder layer includes a first metal solder material, and the first metal solder material includes a metal copper (Cu) and an active metal, and does not include a metal silver (Ag). A thickness of the first sub-solder layer is greater than 6 micrometers. The second sub-solder layer is disposed on a side surface of the first sub-solder layer that is away from the ceramic substrate layer. A composition of the second sub-solder layer includes a second metal solder material, and the second metal solder material includes a metal tin (Sn) and a metal copper (Cu), and does not include a metal silver (Ag). A thickness of the second sub-solder layer is greater than 6 micrometers. The conductive metal layer disposed on a side surface of the second sub-solder layer that is away from the first sub-solder layer.

In order to solve the above-mentioned problems, another one of the technical aspects adopted by the present disclosure is to provide a method for producing a metal ceramic substrate. The method includes: coating a first solder paste onto a side surface of a ceramic substrate layer, and drying the first solder paste at a high temperature to form a first sub-solder layer. The first solder paste includes a first metal solder material and a first organic medium. The first metal solder material includes a metal copper (Cu) and an active metal, and does not include a metal silver (Ag). A thickness of the first sub-solder layer is greater than 6 micrometers. The method further includes: coating a second solder paste onto a side surface of the first sub-solder layer that is away from the ceramic substrate layer, and drying the second solder paste at a high temperature to form a second sub-solder layer. The second solder paste includes a second metal solder material and a second organic medium. The second metal solder material includes a metal tin (Sn) and a metal copper (Cu), and does not include a metal silver (Ag). A thickness of the second sub-solder layer is greater than 6 micrometers. The method further includes: disposing a conductive metal layer on a side surface of the second sub-solder layer that is away from the first sub-solder layer.

Therefore, in the metal ceramic substrate and the method for producing the same provided by the present disclosure, by virtue of “a first sub-solder layer being disposed on a side surface of the ceramic substrate layer, in which a composition of the first sub-solder layer includes a first metal solder material, the first metal solder material includes a metal copper (Cu) and an active metal, and does not include a metal silver (Ag), and a thickness of the first sub-solder layer is greater than 6 micrometers” and “a second sub-solder layer being disposed on a side surface of the first sub-solder layer that is away from the ceramic substrate layer, in which a composition of the second sub-solder layer includes a second metal solder material, the second metal solder material includes a metal tin (Sn) and a metal copper (Cu), and does not include a metal silver (Ag), and a thickness of the second sub-solder layer is greater than 6 micrometers,” the metal solder layer of the metal ceramic substrate does not require the use of the metal silver (Ag).

Through the configuration of the first sub-solder layer and the second sub-solder layer in the above-mentioned metal solder layer, the metal solder layer can improve a bonding force between the ceramic substrate layer and the conductive metal layer. It is worth mentioning that since the metal solder layer does not include any metal silver (Ag), an issue of electro-migration caused by silver residue in the related art can be effectively avoided, and the manufacturing costs can be reduced.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a metal ceramic substrate according to an embodiment of the present disclosure;

FIG. 2 is a schematic view showing two metal solder layers being respectively formed on both sides of the metal ceramic substrate; and

FIG. 3A to 3D are schematic views showing a method for producing the metal ceramic substrate according to the embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### [Metal Ceramic Substrate]

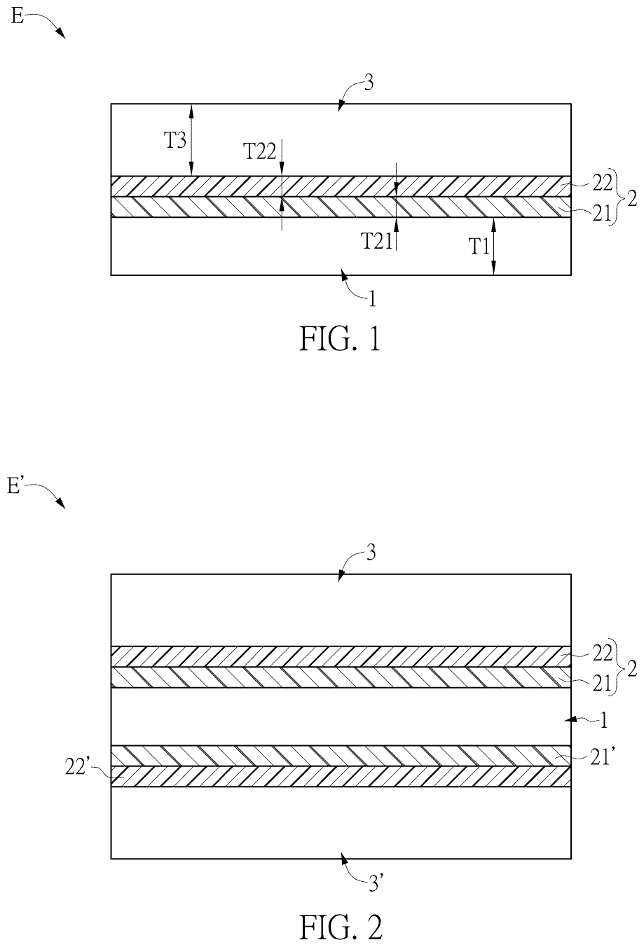

As shown in FIG. 1, an embodiment of the present disclosure provides a metal ceramic substrate E. The metal ceramic substrate E includes a ceramic substrate layer 1, a metal solder layer 2, and a conductive metal layer 3. The metal solder layer 2 is disposed between the ceramic substrate layer 1 and the conductive metal layer 3, so as to connect the ceramic substrate layer 1 and the conductive metal layer 3 together.

More specifically, the metal solder layer 2 includes a first sub-solder layer 21 and a second sub-solder layer 22. The first sub-solder layer 21 is disposed on a side surface of the ceramic substrate layer 1, the second sub-solder layer 22 is disposed on a side surface of the first sub-solder layer 21 that is away from the ceramic substrate layer 1, and the conductive metal layer 3 is disposed on a side surface of the second sub-solder layer 22 that is away from the first sub-solder layer 21. In other words, the first sub-solder layer 21 and the second sub-solder layer 22 are stacked onto each other, the first sub-solder layer 21 is in contact with the ceramic substrate layer 1, and the second sub-solder layer 22 is in contact with the conductive metal layer 3.

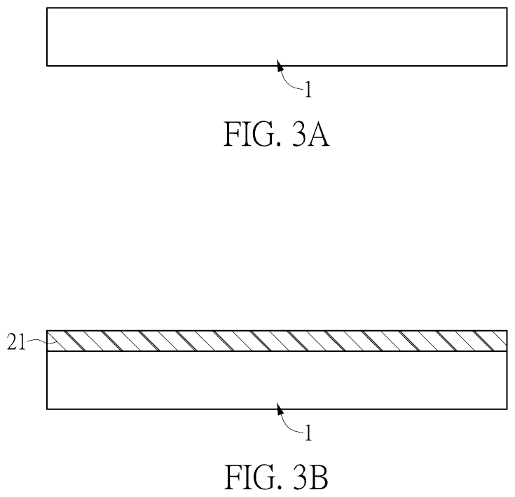

It is worth mentioning that, in the present embodiment, the first sub-solder layer 21, the second sub-solder layer 22, and the conductive metal layer 3 are sequentially disposed on only one side surface of the ceramic substrate layer 1. However, the present disclosure is not limited thereto. For example, as shown in FIG. 2, in another embodiment of the present disclosure, another first sub-solder layer 21′, another second sub-solder layer 22′, and another conductive metal layer 3′ can also be sequentially disposed on another side surface of the ceramic substrate layer 1. In this way, a metal ceramic substrate E′ having the metal solder layer 2 disposed on each of both side surfaces of the ceramic substrate layer 1 can be formed.

The ceramic substrate layer 1 is described in detail below.

The ceramic substrate layer 1 can be at least one of a silicon nitride (SiN) ceramic substrate, a silicon carbide (SiC) ceramic substrate, an aluminum nitride (AlN) ceramic substrate, and an aluminum oxide (Al₂O₃) ceramic substrate.

In the present embodiment, the ceramic substrate layer 1 is preferably the silicon nitride (SiN) ceramic substrate. In addition, a thickness T1 of the ceramic substrate layer 1 can be, for example, between 100 micrometers and 1,000 micrometers, but the present disclosure is not limited thereto.

The first sub-solder layer 21 is described in detail below.

The first sub-solder layer 21 is an active metal layer. The first sub-solder layer 21 is mainly formed of a metal copper (Cu), and includes an active metal. More specifically, a composition of the first sub-solder layer 21 includes a first metal solder material and a first organic medium. The first metal solder material includes the metal copper (Cu) and the active metal. Preferably, the first metal solder material is formed by the metal copper (Cu) and the active metal, and does not contain any metal silver (Ag).

Furthermore, in some embodiments of the present disclosure, the active metal can be selected from the group consisting of: titanium (Ti), zirconium (Zr), tantalum (Ta), niobium (Nb), vanadium (V), hafnium (Hf), and a metal hydride of any one of the above-mentioned metals. For example, the metal hydride can be selected from the group consisting of: titanium hydride (TiH₂), zirconium hydride (ZrH₂), tantalum hydride (TaH₂), niobium hydride (NbH), vanadium hydride (VH₂), and hafnium hydride (H₂Hf₂).

Preferably, the active metal is preferably at least one of titanium (Ti) and titanium hydride (TiH₂).

A weight percent concentration of the first metal solder material in the first sub-solder layer 21 is not less than 70 wt % (weight percent), is preferably not less than 80 wt %, and is more preferably not less than 90 wt %.

In addition, based on a total weight of the first metal solder material being 100 weight percent, a ratio between a content of the metal copper (Cu) and a content of the active metal ranges from 80%:20% to 50%:50% (i.e., the content of the active metal ranges from 20 weight percent to 50 weight percent). Preferably, the ratio between the content of the metal copper (Cu) and the content of the active metal ranges from 65%:35% to 55%:45%. For example, the ratio between the content of the metal copper (Cu) and the content of the active metal is 60%:40%. In other words, in the first metal solder material, the ratio between the content of the metal copper (Cu) and the content of the active metal is greater than 1, but the present disclosure is not limited thereto.

Furthermore, a thickness T21 of the first sub-solder layer 21 is not less than 6 micrometers, is preferably not less than 8 micrometers, and is more preferably between 10 micrometers and 18 micrometers.

The second sub-solder layer 22 is described in detail below.

The second sub-solder layer 22 is a tin-copper metal layer.

More specifically, a composition of the second sub-solder layer 22 includes a second metal solder material and a second organic medium. The second metal solder material includes a metal tin (Sn) and a metal copper (Cu). Preferably, the second metal solder material is formed by the metal tin and the metal copper, and does not contain any metal silver (Ag).

A weight percent concentration of the second metal solder material in the second sub-solder layer 22 is not less than 70 weight percent, is preferably not less than 80 weight percent, and is more preferably not less than 90 weight percent.

In addition, based on a total weight of the second metal solder material being 100 weight percent, a ratio between a content of the metal tin (Sn) and a content of the metal copper (Cu) ranges from 80%:20% to 30%:70% (i.e., the content of the metal tin ranges from 30 weight percent to 80 weight percent). Preferably, the ratio between the content of the metal tin (Sn) and the content of the metal copper (Cu) ranges from 80%:20% to 65%:35%. For example, the ratio between the content of the metal tin and the content of the metal copper is 75%:25%.

In an exemplary embodiment of the present disclosure, the content of the metal copper (Cu) in the first sub-solder layer 21 (e.g., 55% to 65%) is greater than the content of the metal copper (Cu) in the second sub-solder layer 22 (e.g., 20% to 35%), but the present disclosure is not limited thereto.

Furthermore, a thickness T22 of the second sub-solder layer 22 is not less than 6 micrometers, is preferably not less than 8 micrometers, and is more preferably between 10 micrometers and 18 micrometers.

Specifically, a total thickness of the metal solder layer 2 (i.e., a sum of the thickness T21 of the first sub-solder layer 21 and the thickness T22 of the second sub-solder layer 22) is not less than 12 micrometers, is preferably not less than 16 micrometers, and is more preferably between 20 micrometers and 36 micrometers.

The conductive metal layer 3 is described in detail below.

As shown in FIG. 1, the conductive metal layer 3 is disposed on the side surface of the second sub-solder layer 22 that is away from the first sub-solder layer 21.

The conductive metal layer 3 can be, for example, a metal copper foil, a metal aluminum foil, or a copper-aluminum alloy foil (i.e., a Cu—Al alloy foil). In the present embodiment, the conductive metal layer 3 is preferably the metal copper foil. In addition, a thickness T3 of the conductive metal layer 3 can be, for example, between 50 micrometers and 1,200 micrometers, but the present disclosure is not limited thereto.

Through the configuration of the first sub-solder layer 21 and the second sub-solder layer 22 of the metal solder layer 2, the metal solder layer 2 can improve a bonding force between the ceramic substrate layer 1 and the conductive metal layer 3. It is worth mentioning that since the metal solder layer 2 does not include any metal silver (Ag), an issue of electro-migration caused by silver residue in the related art can be effectively avoided, and the manufacturing costs can be reduced.

### [Method for Producing Metal Ceramic Substrate]

The structural and material characteristics of the metal ceramic substrate are described above. A method for producing the metal ceramic substrate of the present disclosure is described in detail below.

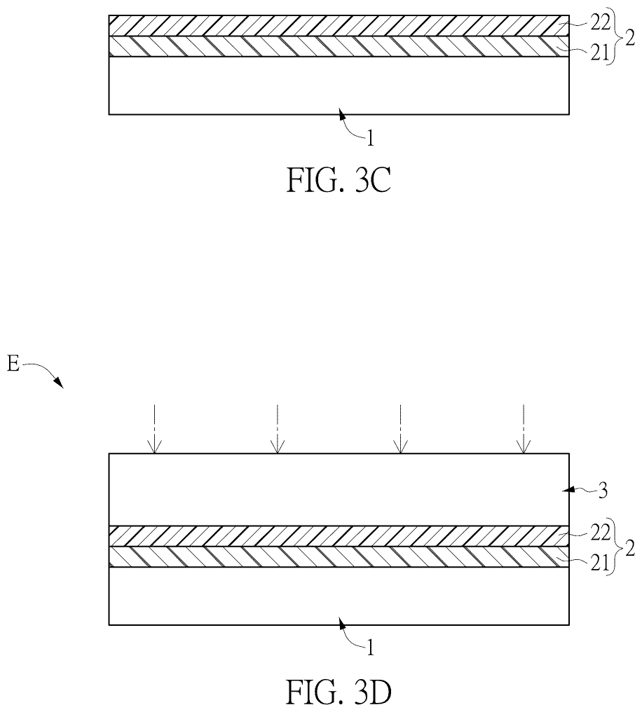

As shown in FIG. 3A to FIG. 3D, an embodiment of the present disclosure also provides a method for producing a metal ceramic substrate, which includes step S110, step S120, step S130, and step S140.

As shown in FIG. 3A, step S110 includes: providing a ceramic substrate layer 1. The ceramic substrate layer 1 can be at least one of a silicon nitride (SiN) ceramic substrate, a silicon carbide (SiC) ceramic substrate, an aluminum nitride (AlN) ceramic substrate, and an aluminum oxide (Al₂O₃) ceramic substrate. Preferably, the ceramic substrate layer 1 is the silicon nitride (SiN) ceramic substrate.

As shown in FIG. 3B, step S120 includes: coating a first solder paste onto a side surface of the ceramic substrate layer 1, and drying the first solder paste at a high temperature to remove a substantial amount of an organic solvent in the first solder paste, so as to form a first sub-solder layer 21. The first solder paste is prepared by mixing a first metal solder material and a first organic medium (e.g., a paste forming agent, an organic solvent, and a thixotropic agent), and is formulated to have a suitable viscosity (e.g., 50 mPa·s to 300 mPa·s), so that the first solder paste can be easily coated onto the ceramic substrate layer 1.

For example, the first solder paste can be coated onto the side surface of the ceramic substrate layer 1 by screen printing, and can be dried at a high temperature of between 90° C. and 110° C. for 5 minutes to 15 minutes, so that most of the organic solvent in the first solder paste is volatilized, and the first sub-solder layer 21 can be formed from the first solder paste.

In some embodiments of the present disclosure, a ratio between a weight of the first metal solder material and a weight of the first organic medium ranges from 70%:30% to 95%:5%, and preferably ranges from 80%:20% to 90%:10%.

The first metal solder material includes a metal copper (Cu) and an active metal. Preferably, the first metal solder material is formed by the metal copper and the active metal, and does not include any metal silver (Ag).

Based on a total weight of the first metal solder material being 100 weight percent, a ratio between a content of the metal copper (Cu) and a content of the active metal ranges from 80%:20% to 50%:50%. Preferably, the ratio between the content of the metal copper (Cu) and the content of the active metal ranges from 65%:35% to 55%:45%. For example, the ratio between the content of the metal copper (Cu) and the content of the active metal is 60%:40%.

In the first organic medium, a ratio of a weight of the paste forming agent, a weight of the organic solvent, and a weight of the thixotropic agent can be 20% to 30%:50% to 70%:1% to 5%.

The paste forming agent can be selected from the group consisting of: silicone oil, white oil, polyvinyl alcohol, acrylic resin, nitrocellulose, ethyl cellulose, dimethyl phthalate, and carboxy-methyl cellulose. Preferably, the paste forming agent is ethyl cellulose.

The organic solvent can be selected from the group consisting of: ethylene glycol butyl ether acetate, diethylene glycol, tri-ethanolamine, butyl cellosolve, tert-butanol, N,N-dimethylformamide, terpineol, and nonyl phenol polyethylene glycol ether. Preferably, the organic solvent is terpineol or ethylene glycol butyl ether acetate.

The thixotropic agent can be at least one selected from the group consisting of: polyamide wax, hydrogenated castor oil, and polyurea. Preferably, the thixotropic agent is polyamide wax.

However, the present disclosure is not limited to the above-mentioned implementations. As long as the metal solder material and the organic medium can be formulated into a solder paste having a viscosity suitable for being coated onto a ceramic substrate (which facilitates formation of a solder layer), the technical solution falls under the spirit and scope of the present disclosure.

As shown in FIG. 3C, step S130 includes: coating a second solder paste onto a side surface of the first sub-solder layer 21 that is away from the ceramic substrate layer 1, and drying the second solder paste at a high temperature to remove a substantial amount of an organic solvent in the second solder paste, so as to form a second sub-solder layer 22.

The second solder paste is prepared by mixing a second metal solder material and a second organic medium (e.g., a paste forming agent, an organic solvent, and a thixotropic agent), and is formulated to have a suitable viscosity (e.g., 50 mPa·s to 300 mPa's), so that the second solder paste can be easily coated onto the first sub-solder layer 21.

For example, the second solder paste can be coated onto the first sub-solder layer 21 by screen printing, and can be dried at a high temperature of between 90° C. and 110° C. for 5 minutes to 15 minutes, so that most of the organic solvent in the second solder paste is volatilized, and the second sub-solder layer 22 can be formed from the second solder paste.

In some embodiments of the present disclosure, a ratio between a weight of the second metal solder material and a weight of the second organic medium ranges from 70%:30% to 95%:5%, and preferably ranges from 80%:20% to 90%:10%.

The second metal solder material includes a metal tin (Sn) and a metal copper (Cu). Preferably, the second metal solder material is formed by the metal tin and the metal copper, and does not include any metal silver (Ag).

Based on a total weight of the second metal solder material being 100 weight percent, a ratio between a content of the metal tin (Sn) and a content of the metal copper (Cu) ranges from 80%:20% to 30%:70%. Preferably, the ratio between the content of the metal tin (Sn) and the content of the metal copper (Cu) ranges from 80%:20% to 65%:35%. For example, the ratio between the content of the metal tin and the content of the metal copper is 75%:25%. The content and material types of the second organic medium in the second solder paste are similar to those in the first solder paste, and will not be reiterated herein.

As shown in FIG. 3D, step S140 includes: disposing a conductive metal layer 3 on a side surface of the second sub-solder layer 22 that is away from the first sub-solder layer 21, so that the conductive metal layer 3 can be connected to the ceramic substrate layer 1 through the first sub-solder layer 21 and the second sub-solder layer 22.

The conductive metal layer 3 can be a metal copper foil, a metal aluminum foil, or a copper aluminum alloy foil. In the present embodiment, the conductive metal layer 3 is preferably the metal copper foil.

Step S140 further includes: performing a high-temperature vacuum sintering process to tightly connect the conductive metal layer 3 to the ceramic substrate layer 1 through a metal solder layer 2 formed by the first sub-solder layer 21 and the second sub-solder layer 22.

An operation temperature of the high-temperature vacuum sintering process is between 600° C. and 900° C., and is preferably between 700° C. and 900° C.

It is worth mentioning that, in the above-mentioned high-temperature vacuum sintering process, the active metal (e.g., Ti) in the first sub-solder layer 21 can wet a surface of the ceramic substrate layer 1, and the active metal can react with a ceramic material (e.g., SiN) to form compounds, such as titanium nitride (TiN), titanium silicon oxide (TiSi), and/or titanium disilicate (TiSi₂). In this way, a bonding force between the conductive metal layer 3 and the ceramic substrate layer 1 can be improved. In addition, when the metal tin (Sn) of the second sub-solder layer 22 and the metal copper (Cu) of the second sub-solder layer 22 are heated in the high-temperature vacuum sintering process, the metal tin and the metal copper can be melt in a fluid state and react with each other, so that the conductive metal layer 3 and the ceramic substrate layer 1 have a good bonding force.

For example, when the operation temperature of the high-temperature vacuum sintering process is greater than 600° C., the metal tin can first react with the metal copper to form a Cu₃Sn alloy. Furthermore, the Cu₃Sn alloy can react with more of the metal tin to form a Cu₆Sn₅ alloy. Accordingly, the second sub-solder layer 22 can be connected to the conductive metal layer 3 more tightly, such that the bonding force between the conductive metal layer 3 and the ceramic substrate layer 1 can be improved.

According to the above configuration, the metal solder layer 2 can be used to improve the bonding force between the ceramic substrate layer 1 and the conductive metal layer 3. It is worth mentioning that since the metal solder layer 2 does not include any metal silver (Ag), the issue of electro-migration caused by silver residue in the related art can be effectively avoided, and the manufacturing costs can be reduced.

### [Experimental Data and Test Results]

Hereinafter, a detailed description will be provided with reference to Exemplary Examples 1 to 3.

A preparation method of Exemplary Example 1 includes: coating, according to the conditions shown in Table 1, a first solder paste that includes a first metal solder material and a first organic medium onto a side surface of a ceramic substrate layer, and drying the first solder paste at a high temperature (i.e., 100° C.), so as to form a first sub-solder layer. The first metal solder material includes copper (Cu) powders and titanium (Ti) powders with a weight ratio of 60:40, and a thickness of the first sub-solder layer is 12 micrometers. In addition, the ceramic substrate layer is a silicon nitride ceramic substrate. Then, a second solder paste that includes a second metal solder material and a second organic medium is coated onto the first sub-solder layer, and is dried at a high temperature (i.e., 100° C.) to form a second sub-solder layer. The second metal solder material includes tin (Sn) powders and copper (Cu) powders with a weight ratio of 75:25, and a thickness of the second sub-solder layer is 12 micrometers. In each of the first solder paste and the second solder paste, a weight ratio between the metal solder material and the organic medium is 80:20. In the organic medium, a paste forming agent is ethyl cellulose, an organic solvent is ethylene glycol butyl ether acetate, and a thixotropic agent is polyamide wax. A weight ratio of the paste forming agent, the organic solvent, and the thixotropic agent is 25:60:15. The first solder paste and the second solder paste do not contain any metal silver. Afterwards, a metal copper foil is further disposed on the second sub-solder layer to form a metal ceramic substrate.

In Exemplary Example 1, the metal ceramic substrate is further subjected to high-temperature vacuum sintering at a brazing temperature of 855° C. Then, a temperature of the metal ceramic substrate is lowered to a room temperature (i.e., 25° C.), and a tensile force test is performed on the metal ceramic substrate.

The preparation methods of Exemplary Example 2 and Exemplary Example 3 are substantially the same as the above-mentioned Exemplary Example 1, and their differences are listed in Table 1 below.

The tensile force test is used to measure a tensile force between the metal copper foil and the ceramic substrate according to the JIS-C-6481 standard. A measurement temperature is 25° C. If the tensile force is greater than 100 N/cm, a bonding strength is evaluated as good. If the tensile force falls within a range of from 50 N/cm to 100 N/cm, the bonding strength is evaluated as normal. If the tensile force is less than 50 N/cm, the bonding strength is evaluated as poor.

TABLE 1

first sub-solder layer

| | metal | weight | thickness |
|---|---|---|---|
| Items | composition | ratio | (μm) |
| Exemplary Example 1 | Cu—Ti | 60:40 | 12 |
| Exemplary Example 2 | Cu—Ti | 60:40 | 6 |
| Exemplary Example 3 | Cu—Ti | 60:40 | 6 |

| | second sub-solder layer | | | brazing | tensile |
|---|---|---|---|---|---|
| | metal | weight | thickness | temperature | force |
| Items | composition | ratio | (μm) | (° C.) | (N/cm) |
| Exemplary | Sn—Cu | 75:25 | 12 | 855 | 106 |
| Example 1 | | | | | (good) |
| Exemplary | Sn—Cu | 75:25 | 6 | 855 | failed |
| Example 2 | | | | | |
| Exemplary | Sn—Cu | 75:25 | 12 | 855 | 34.72 |
| Example 3 | | | | | (poor) |

### [Test Results and Discussion]

From the test results shown in Table 1, the tensile force of the metal ceramic substrate of Exemplary Example 1 is 106 N/cm. Compared with the metal ceramic substrates of Exemplary Examples 2 and 3, the metal ceramic substrate of Exemplary Example 1 has better tensile strength performance. Exemplary Example 1 shows that the first sub-solder layer and the second sub-solder layer need to have a specific composition and be within a specific thickness range, so as to enable the metal copper foil and the ceramic substrate layer to have an improved bonding force. The thickness of the first sub-solder layer and that of the second sub-solder layer in Exemplary Example 2 are thin (6 μm), and are not within an optimal range, so that the tensile strength performance of Exemplary Example 2 is not good. The thickness of the first sub-solder layer in Exemplary Example 3 is thin (6 μm), and is not within the optimal range, so that the tensile strength performance of Exemplary Example 3 is not good.

It is worth mentioning that the metal ceramic substrate of the above-mentioned Exemplary Example 1 can still have good tensile strength performance even if the metal solder layer does not contain any metal silver, which is a breakthrough from the limitation of using the metal silver in an active metal layer in the related art.

### BENEFICIAL EFFECTS OF THE EMBODIMENTS

In conclusion, in the metal ceramic substrate and the method for producing the same provided by the present disclosure, by virtue of “a first sub-solder layer being disposed on a side surface of the ceramic substrate layer, in which a composition of the first sub-solder layer includes a first metal solder material, the first metal solder material includes a metal copper (Cu) and an active metal, and does not include a metal silver (Ag), and a thickness of the first sub-solder layer is greater than 6 micrometers” and “a second sub-solder layer being disposed on a side surface of the first sub-solder layer that is away from the ceramic substrate layer, in which a composition of the second sub-solder layer includes a second metal solder material, the second metal solder material includes a metal tin (Sn) and a metal copper (Cu), and does not include a metal silver (Ag), and a thickness of the second sub-solder layer is greater than 6 micrometers,” the metal solder layer of the metal ceramic substrate does not require the use of the metal silver (Ag).

Through the configuration of the first sub-solder layer and the second sub-solder layer in the above-mentioned metal solder layer, the metal solder layer can improve the bonding force between the ceramic substrate layer and the conductive metal layer. It is worth mentioning that since the metal solder layer does not include any metal silver (Ag), the issue of electro-migration caused by silver residue in the related art can be effectively avoided, and the manufacturing costs can be reduced.

Lastly, through etching a circuit pattern on the ceramic substrate by exposure and development, the metal ceramic substrate of the present disclosure can be applied to a high-power module for energy conversion, an electric vehicle, and a charging system.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A metal ceramic substrate, comprising:
a ceramic substrate layer;
a metal solder layer including:
a first sub-solder layer disposed on a side surface of the ceramic substrate layer, wherein a composition of the first sub-solder layer includes a first metal solder material, and the first metal solder material includes a metal copper (Cu) and an active metal, and does not include a metal silver (Ag), and wherein a thickness of the first sub-solder layer is greater than 6 micrometers; and
a second sub-solder layer disposed on a side surface of the first sub-solder layer that is away from the ceramic substrate layer, wherein a composition of the second sub-solder layer includes a second metal solder material, and the second metal solder material includes a metal tin (Sn) and a metal copper (Cu), and does not include a metal silver (Ag), and wherein a thickness of the second sub-solder layer is greater than 6 micrometers; and
a conductive metal layer disposed on a side surface of the second sub-solder layer that is away from the first sub-solder layer.

2. The metal ceramic substrate according to claim 1, wherein, based on a total weight of the first metal solder material being 100 weight percent, a ratio between a content of the metal copper (Cu) and a content of the active metal ranges from 80%:20% to 50%:50%; wherein, based on a total weight of the second metal solder material being 100 weight percent, a ratio between a content of the metal tin (Sn) and a content of the metal copper (Cu) ranges from 80%:20% to 30%:70%.

3. The metal ceramic substrate according to claim 1, wherein, based on a total weight of the first metal solder material being 100 weight percent, a ratio between a content of the metal copper (Cu) and a content of the active metal ranges from 65%:35% to 55%:45%; wherein, based on a total weight of the second metal solder material being 100 weight percent, a ratio between a content of the metal tin (Sn) and a content of the metal copper (Cu) ranges from 80%:20% to 65%:35%; wherein the entire metal solder layer does not contain the metal silver (Ag).

4. The metal ceramic substrate according to claim 1, wherein a content of the metal copper (Cu) of the first sub-solder layer is greater than a content of the metal copper (Cu) of the second sub-solder layer.

5. The metal ceramic substrate according to claim 1, wherein the thickness of the first sub-solder layer is between 10 micrometers and 18 micrometers, and the thickness of the second sub-solder layer is between 10 micrometers and 18 micrometers.

6. The metal ceramic substrate according to claim 1, wherein the active metal is selected from the group consisting of titanium (Ti), zirconium (Zr), tantalum (Ta), niobium (Nb), vanadium (V), hafnium (Hf), titanium hydride (TiH₂), zirconium hydride (ZrH₂), tantalum hydride (TaH₂), niobium hydride (NbH), vanadium hydride (VH₂), and hafnium hydride (H₂Hf₂); wherein the ceramic substrate layer is selected from the group consisting of a silicon nitride ceramic substrate, a silicon carbide ceramic substrate, an aluminum nitride ceramic substrate, and an alumina ceramic substrate; wherein the conductive metal layer is selected from the group consisting of a metal copper foil, a metal aluminum foil, and a copper-aluminum alloy foil.

7. A method for producing a metal ceramic substrate, comprising:
coating a first solder paste onto a side surface of a ceramic substrate layer, and drying the first solder paste at a high temperature to form a first sub-solder layer; wherein the first solder paste includes a first metal solder material and a first organic medium, and the first metal solder material includes a metal copper (Cu) and an active metal, and does not include a metal silver (Ag); wherein a thickness of the first sub-solder layer is greater than 6 micrometers;
coating a second solder paste onto a side surface of the first sub-solder layer that is away from the ceramic substrate layer, and drying the second solder paste at a high temperature to form a second sub-solder layer; wherein the second solder paste includes a second metal solder material and a second organic medium, and the second metal solder material includes a metal tin (Sn) and a metal copper (Cu), and does not include a metal silver (Ag); wherein a thickness of the second sub-solder layer is greater than 6 micrometers; and
disposing a conductive metal layer onto a side surface of the second sub-solder layer that is away from the first sub-solder layer.

8. The method according to claim 7, wherein, in the first sub-solder layer, a weight percentage concentration of the first metal solder material is not less than 70 wt %; wherein, in the second sub-solder layer, a weight percentage concentration of the second metal solder material is not less than 70 wt %.

9. The method according to claim 8, wherein, based on a total weight of the first metal solder material being 100 weight percent, a ratio between a content of metal copper (Cu) and a content of the active metal ranges from 80%:20% to 50%:50%; wherein, based on a total weight of the second metal solder material being 100 weight percent, a ratio between a content of the metal tin (Sn) and a content of the metal copper (Cu) ranges from 80%:20% to 30%:70%.

10. The method according to claim 8, further comprising: performing a high-temperature vacuum sintering process to tightly connect the conductive metal layer to the ceramic substrate layer through a metal solder layer formed by the first sub-solder layer and the second sub-solder layer; wherein an operation temperature of the high-temperature vacuum sintering process is between 600° C. and 900° C.
